(19) United States
(12) Patent Application Publication
(10) Pub. No.: US 2003/0100195 A1
(43) Pub. Date: May 29, 2003

(54) Semiconductor device having an indium doped dielectric layer located therein and a method of manufacture therefor

(75) Inventors: Julia C. Duncan, Mertztown, PA (US); William J. Minford, Northampton, PA (US); John W. Osenbach, Kutztown, PA (US)

Correspondence Address: HITT GAINES & BOISBRUN P.C., P.O. BOX 832570, RICHARDSON, TX, 75083, US

(73) Assignee: Agere Systems Inc., Allentown, PA

(21) Appl. No.: 09/997,650

(22) Filed: Nov. 28, 2001

(51) Int. Cl. H01L 21/31; H01L 21/469

(52) U.S. Cl. 438/783; 438/778

(57) ABSTRACT

The present invention provides a semiconductor device, a method of manufacture therefor, and an integrated circuit including the semiconductor device. The semiconductor device includes a semiconductor substrate and an indium doped dielectric layer located over the semiconductor substrate.

### TECHNICAL FIELD OF THE INVENTION

The present invention is directed, in general, to an integrated device and, more specifically, to a semiconductor device having an indium doped dielectric layer located therein and a method of manufacture therefor.

### BACKGROUND OF THE INVENTION

Many silicon-based devices are sensitive to mobile ion contaminates. Device instabilities, including but not limited to changes in transistor transfer characteristics, breakdown voltage, leakage currents, etc., that are time, temperature and electric field dependent, arise from such mobile ion contaminants. In addition, optoelectronic devices such as indium-based lasers, photodetectors, and modulators, are also sensitive to the mobile ion contaminants. For example, such optoelectronic devices may exhibit instabilities in an optical transfer function over time as a result of the mobile ionic contaminants.

As a result of the aforementioned mobile ion contaminants, an increased amount of effort has been expended identifying ways to prevent mobile ion contaminants from having a negative influence on device performance and longevity. During such efforts, certain techniques have been found to reduce the negative effects mobile ion contaminants have on performance and longevity. One of the more simple techniques employed to reduce the effects of mobile ion contaminants is to prevent the mobile ion contaminants from being introduced into the device. This may be accomplished using many methods, however, this may particularly be accomplished by using ultra-pure chemical reagents, ultra-pure metal sources, and physical barrier protection. The physical barrier protection may be in the form of masks and gloves, protecting the device from human touch and breath.

An additional technique employed to reduce the effects of mobile ion contaminants includes using a barrier layer of silicon nitride or another similar material. The barrier layer tends to provide a slower diffusion path for mobile ion contaminant migration. Additionally, the mobile ion contaminants may be eliminated during an oxidation process by adding chlorinated species to the oxidation ambient, or alternatively, gettered by depositing a phosphorous doped silicate glass.

Although, individually or in combination, these techniques have been proven somewhat effective in the silicon-based industries, they are often unavailable for use in non-silicon-based technologies that may also be sensitive to mobile ion contamination. As previously recited, one of such non-silicon-based technologies is the indium based optoelectronic device technology.

In the past, getter materials including phosphorous-doped oxides were used to tie up the mobile ion contaminants in the optoelectronic devices. Unfortunately, there are at least two potential reliability issues that phosphorous doping presents. While the effectiveness of the phosphorous-doped oxides to getter the mobile ion contaminants increases with increased phosphorous doping, the propensity for moisture induced leaching of phosphorous, also increases. This problem is compounded when the phosphorous-doped oxides are deposited at low temperatures (e.g., temperatures less than about 500° C. This tends to lead to an increase in the susceptibility of the metallization to corrosion. Additionally, the phosphorous can polarize when subjected to electric fields, which leads to device instability.

Accordingly, what is needed in the art is a material that getters unwanted contaminants, however, a material that does not experience the problems experienced by the prior art.

### SUMMARY OF THE INVENTION

To address the above-discussed deficiencies of the prior art, the present invention provides a semiconductor device, a method of manufacture therefor, and an integrated circuit including the semiconductor device. The semiconductor device includes a semiconductor substrate and an indium doped dielectric layer located over the semiconductor substrate.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features may not be drawn to scale. In fact, the dimensions of the various features may be arbitrarily increased or reduced for clarity of discussion. Reference is now made to the following descriptions taken in conjunction with the accompanying drawings, in which:

FIG. 1 illustrates a graphical representation depicting how an indium doped dielectric layer may getter lithium when located over a lithium niobate layer;

FIG. 2 illustrates a cross-sectional view of one embodiment of a semiconductor device, which provides one environment where an indium doped dielectric layer that is in accordance with the principles of the present invention, may be used;

FIG. 3 illustrates a cross-sectional view of an integrated circuit, which provides one environment where the semiconductor device 200 may be used;

FIG. 4 illustrates a cross-sectional view of another embodiment of a semiconductor device, which provides a different environment where an indium doped dielectric layer that is in accordance with the principles of the present invention, may be used; and

FIG. 5 illustrates a cross-sectional view of an integrated circuit, which provides another environment where the semiconductor device may be used.

### DETAILED DESCRIPTION

It is well known in the art that certain materials, such as many of those currently used as dielectrics in microelectronic and optoelectronic devices, may be used in an attempt to getter undesirable mobile ion contaminants within such devices. Also well known, is that many of the traditional gettering materials include one drawback or another as previously discussed. What is not known, however, is that indium doped dielectric layers may be used in place of, or in conjunction with, the prior art dielectric materials, and that the indium doped dielectric layers may be used without experiencing many of the problems experienced by using the prior art dielectric materials.

In a broad sense, the above-mentioned indium doped dielectric layers may be used as a dielectric layer in any device where there is a desire to getter mobile ion contaminants and provide an insulative function. The indium doped dielectric layers are particularly useful in gettering mobile ions such as lithium, sodium or potassium. It should be noted, however, that the present invention should not be limited to gettering such mobile ions. Because the indium doped dielectric layers are very good at gettering mobile ion contaminants and have a low dielectric constant, the indium doped dielectric layers do not experience many of the problems associated with using the prior art dielectric layers.

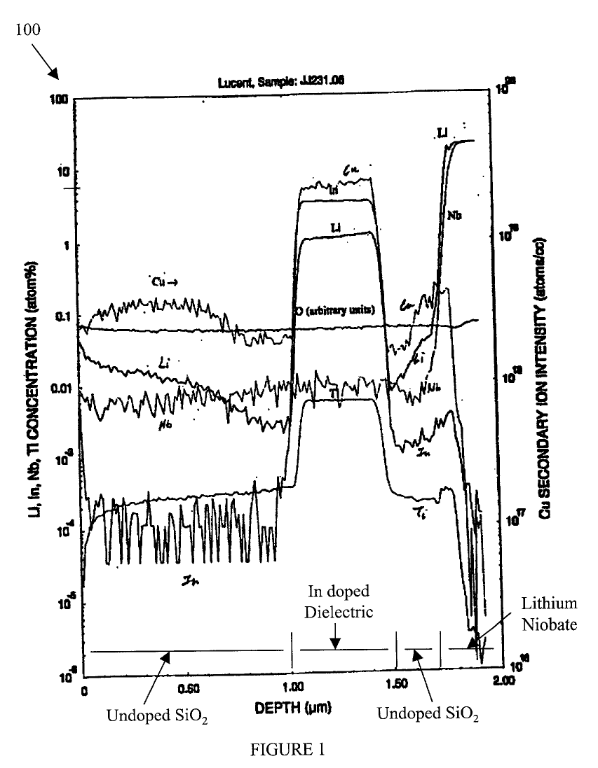

Turning initially to FIG. 1, illustrated is a graphical representation 100 depicting how an indium doped dielectric layer may getter lithium when located over a lithium niobate layer. We have chosen to study lithium for the following reasons: 1) lithium is the smallest of the mobile alkali ions, and 2) it moves faster than sodium or potassium. Additionally, its outer electron configuration is similar to sodium and potassium, thus we expect lithium to be gettered in a matter similar to sodium and potassium. A controlled source of lithium is LiNbO₃. As such, we used LiNbO₃ substrates as the lithium source when studying if an indium-doped silicon dioxide layer could in fact getter lithium.

In the illustrative representation, a first undoped SiO₂ layer is deposited over the lithium niobate layer. The first undoped SiO₂ layer, in the embodiment illustrated herein, has a thickness of about 0.25 μm. An indium doped dielectric layer is then deposited over the undoped SiO2 layer. In this particular embodiment, the indium doped dielectric layer has a thickness of about 0.5 μm. Located over the indium doped dielectric layer is a second undoped SiO₂ layer having a thickness of about 1 μm. While thicknesses have been discussed with respect to the various layers, one skilled in the art understands that the thicknesses are given for illustrative purposes only, and do not limit the present invention. Following the depositions, the sample may be annealed in wet ambient at 500° C. for 5 hours. The anneal provides the driving force for the lithium from the substrate to enter the silicon dioxide layers. The sample may then be subjected to secondary Ion Mass Spectrometry (SIMS) depth profiling.

As illustrated in FIG. 1, the amount of lithium present in the indium doped dielectric layer is much higher than the amount of lithium present in either the first or second undoped SiO2 layers. For example, the concentration of lithium in the indium doped dielectric layer is about 1 atomic weight percent, wherein the concentration of lithium in the first and second undoped SiO2 layers is about 0.07 atomic weight percent. This graphical representation clearly illustrates how the indium doped dielectric layer acts as a getter to lithium.

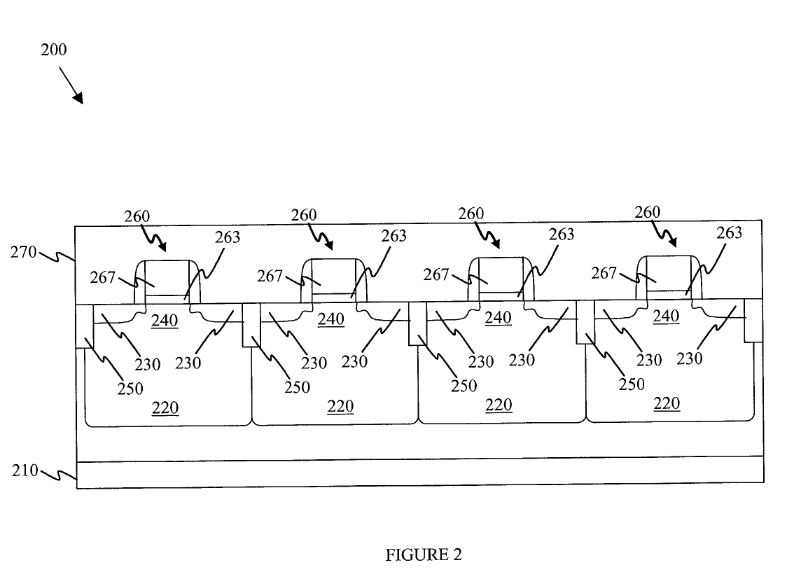

Referring to FIG. 2, illustrated is one embodiment of a semiconductor device 200, which provides one environment where an indium doped dielectric layer that is in accordance with the principles of the present invention, may be used. The semiconductor device 200, which in the embodiment illustrated in FIG. 2 is metal oxide semiconductor (MOS) device, includes a semiconductor substrate 210. The semiconductor substrate 210 may be any layer located in an integrated circuit, including a layer located at the wafer level, such as an epitaxial layer, or a layer located within the wafer. A “semiconductor” substrate may be defined as any substrate that includes a class of solids whose electrical conductivity is between that of a conductor and that of an insulator, wherein it approaches that of the conductor at higher temperatures and that of an insulator at lower temperatures. For example, in one embodiment, a semiconductor material may include any element within groups 3-5 of the periodic table. However, in another embodiment a semiconductor material may be any material that can have a bandgap of less than about 4 electron volts (eV).

Located within the semiconductor substrate 210 in the embodiment illustrated in FIG. 1 are tub regions 220. The tub regions 220, which may be a collection of N-tub regions and P-tub regions, have conventional source/drain regions 230 located therein. Located between the source/drain regions 230 in the exemplary embodiment shown in FIG. 2, is an active region 240, for example a channel region. Also, located partially within the tub regions 220 are isolation structures 250. In the illustrative embodiment, the isolation structures 250 are shallow trench isolation structures, however, it should be understood that any known or hereafter discovered isolation structure is within the scope of the present invention.

Located over the semiconductor substrate 210 are gate structures 260. The gate structures 260, similar to all gate structures, include gate oxides 263 and gate electrodes 267. The formative structure and function of these structures are well known and understood. For this reason, no further discussion is needed.

Uniquely located over the active region 240, thus over the semiconductor substrate 210, is an indium doped dielectric layer 270. In the particular example illustrated in FIG. 2, the indium doped dielectric layer 270 is acting as an interlevel dielectric layer and comprises an indium doped oxide layer, for example indium doped silicon dioxide. Because the indium doped dielectric layer 270 is located over the active region 240, it substantially reduces the amount of mobile ion contaminants that contact the active region 240.

The indium doped dielectric layer 270 may be formed having a wide range of thicknesses, while maintaining its ability to getter mobile ion contaminants. In an exemplary embodiment, the indium doped dielectric layer 270 is formed to a thickness ranging from about 400 nm to about 1200 nm. It should be noted that a desired thickness of the indium doped dielectric layer 270 is only minimally dependent on the ability of the indium doped dielectric layer 270 to getter the mobile ion contaminants and minimally dependent on the concentration of the mobile ions. In actuality, the desired thickness is mostly dependent on the particular use of the indium doped dielectric layer 270.

The indium doped dielectric layer 270 may be formed using various processes. For example, in the illustrative embodiment shown in FIG. 2 the indium doped dielectric layer 270 is deposited using a conventional physical vapor deposition (PVD) sputtering process. This may require co-sputtering a silicon target and an indium oxide target in the presence of both argon and oxygen. Alternatively, however, a single silicon/indium oxide target could be used. The single silicon/indium oxide target could comprise, in an advantageous embodiment, a silicon dioxide substrate having holes drilled therein, wherein the holes are filled with an indium material.

Additionally, in an exemplary embodiment, the argon and oxygen are supplied to a chamber of the sputtering process at a gas flow rate ranging from about 10 ccm to about 35 ccm. Additionally, while the indium doped dielectric layer 270 is being formed, a temperature of the semiconductor substrate 210 may be increased from room temperature to a temperature of about 70° C. Likewise, a pressure ranging from about 4 mTorr to about 8 mTorr and a radio frequency (RF) ranging from about 50 watts to about 550 watts, may be used.

What desirably results, is an indium doped dielectric layer 270 having an indium concentration ranging from about 1 mole weight percent to about 15 mole weight percent, and more preferably an indium concentration ranging from about 4 mole weight percent to about 8 mole weight percent, and even more preferably an indium concentration of about 7 mole weight percent. While it has been specifically mentioned that the indium doped dielectric layer 270 may be formed using a PVD process, one skilled in the art understands that other similar processes, including a plasma enhanced chemical vapor deposition (PECVD) or another similar process, may be used.

One particular example of using the indium doped dielectric layer 270 within the semiconductor device 200 has been illustrated in FIG. 2. However, other uses for the indium doped dielectric layer 270 within the semiconductor device 200 are also within the scope of the present invention. For example, the indium doped dielectric layer 270 may be used in place of a traditional final nitride passivation layer. In such an example, the indium doped dielectric layer 270 could be formed using a process similar to those described above, and therefore, would act as a final passivation and mobile ion contamination gettering layer.

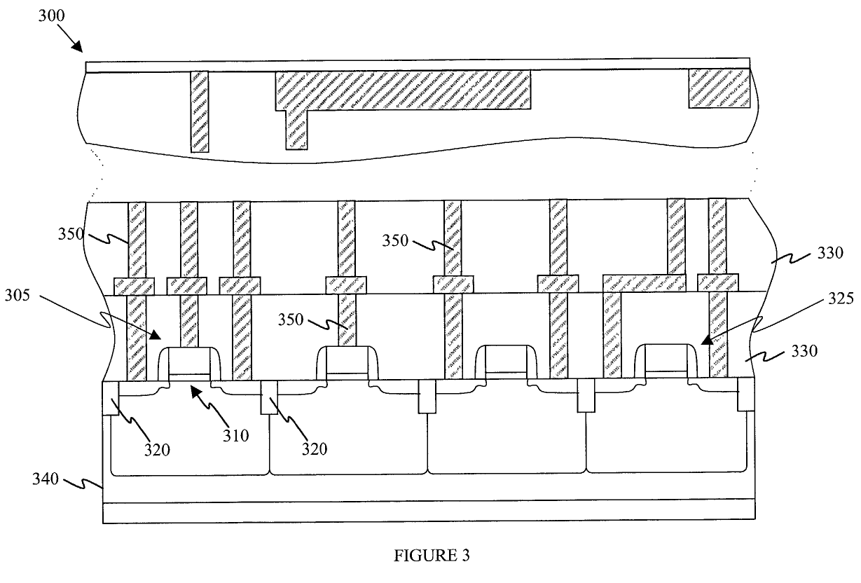

Turning to FIG. 3, illustrated is a cross-sectional view of an integrated circuit 300, which provides one environment where a semiconductor device in accordance with the principles of the present invention, may be used. The integrated circuit 300 may include first and second semiconductor device, including CMOS devices, BiCMOS devices, field effect transistors, generally, or other devices commonly incorporated into integrated circuit designs. Shown in FIG. 3 are components of the integrated circuit 300, including: a first semiconductor device 305 having a gate structure 310 located between conventionally formed isolation structures 320, a second semiconductor device 325, indium doped dielectric layers 330 located over the first and second devices 305, 325 and a semiconductor substrate 340, and interconnect structures 350. The interconnect structures 350, among other things, connect the gate structure 310 to other areas of the integrated circuit 300, thus, forming an operational integrated circuit.

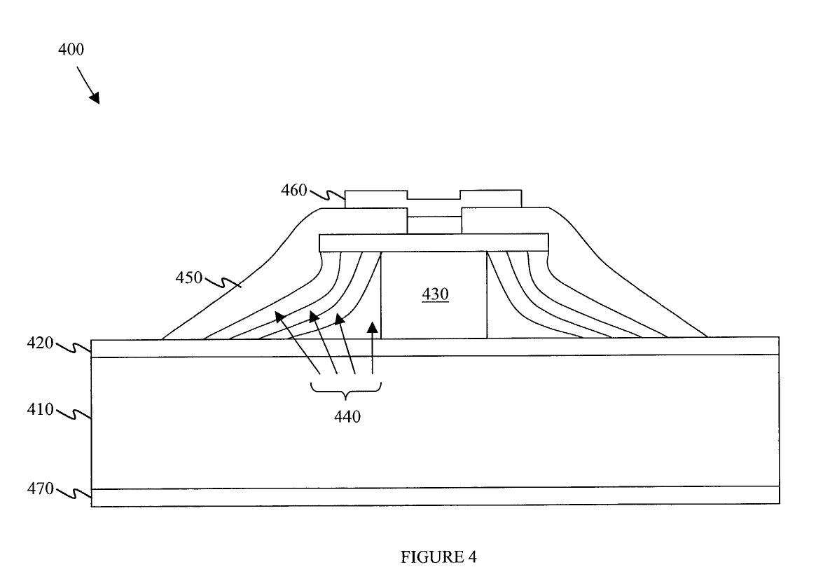

Turning to FIG. 4, illustrated is another embodiment of a semiconductor device 400, which provides another environment where an indium doped dielectric layer may be used. The semiconductor device 400, which in the embodiment illustrated in FIG. 4 is a laser device, includes a semiconductor substrate 410 having a buffer layer 420 located thereover. In the illustrative embodiment shown in FIG. 4, the semiconductor substrate 410 comprises an indium phosphide substrate, however, other substrates comprising semiconductive materials are within the scope of the present invention. Located over the buffer layer 420 is a heterostructure 430, having blocking layers 440 located on opposing sides thereof. The heterostructure 430 performs as an active region of the semiconductor device 400. In the illustrative embodiment, the blocking layers 430 comprises a PNIN blocked layer structure. It should be noted, however, that other blocking layer structures are within the scope of the present invention.

Formed over the heterostructure 430, the blocking layers 440, and the semiconductor substrate 410 is an indium doped dielectric layer 450. The indium doped dielectric layer 450, as compared to prior art oxides located within many semiconductor devices, acts as a getter layer for mobile ion contaminants. Additionally, because the indium doped dielectric layer comprises indium rather than phosphorous, the semiconductor device 400 has a substantially lower parasitic capacitance than the prior art devices. The lower parasitic capacitance plays an important role in the improved operating speed of the semiconductor device 400.

Located over the indium doped dielectric layer 450, and electrically contacting the heterostructure 430, is a P-metal contact 460. Additionally, located over an opposing side of the semiconductor substrate 410 is an N-metal contact 470. The P-metal contact 460 and the N-metal contact 470 help bias the semiconductor device 400 for operation thereof.

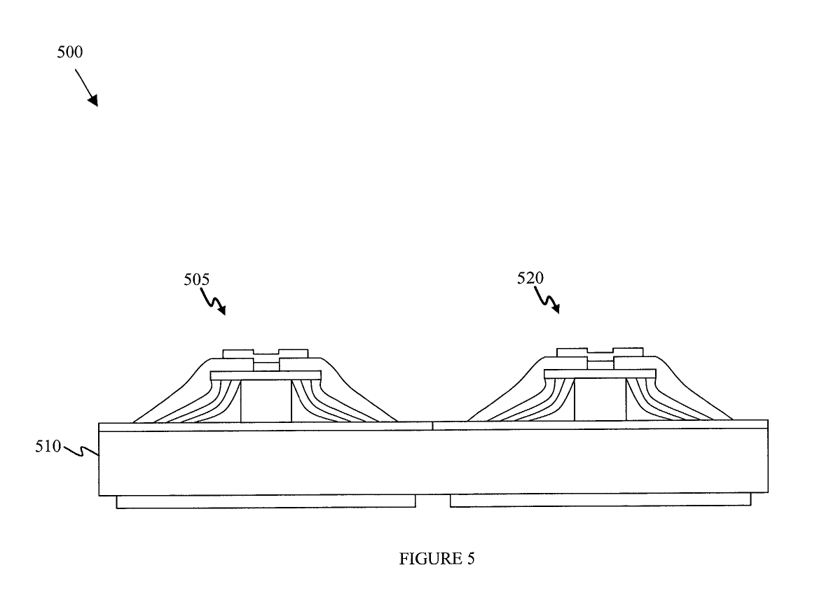

Turning to FIG. 5 illustrated is a cross-sectional view of an integrated circuit 500, which provides another environment where a semiconductor device constructed in accordance with the principles of the present invention, may be used. The integrated circuit 500 includes a first semiconductor device 505 located over a semiconductor substrate 510. The integrated circuit further includes a second semiconductor device 520 that is located proximate the first semiconductor device 505 and over the semiconductor substrate 510. While the first semiconductor device 505 and the second semiconductor device 520 are illustrated as lasers, one skilled in the art understands other optoelectronic devices, such as photodetectors and modulators, are within the scope of the present invention.

Although the present invention has been described in detail, those skilled in the art should understand that they can make various changes, substitutions and alterations herein without departing from the spirit and scope of the invention in its broadest form.

What is claimed is:

1. A semiconductor device, comprising:
a semiconductor substrate; and
an indium doped dielectric layer located over the semiconductor substrate.

2. The semiconductor device as recited in claim 1 wherein the indium doped dielectric layer is an interlevel dielectric layer.

3. The semiconductor device as recited in claim 1 wherein the indium doped dielectric layer is an indium doped silicon dioxide layer.

4. The semiconductor device as recited in claim 1 wherein the indium doped dielectric layer has a thickness ranging from about 400 nm to about 1200 nm.

5. The semiconductor device as recited in claim 1 wherein the indium doped dielectric layer has an indium concentration ranging from about 1 mole weight percent to about 15 mole weight percent.

6. The semiconductor device as recited in claim 1 further including an active region, wherein the indium doped dielectric layer is located over the active region.

7. The semiconductor device as recited in claim 6 wherein the active region is a channel region of a metal oxide semiconductor device.

8. The semiconductor device as recited in claim 6 wherein the active region is an active region of an optoelectronic device.

9. A method of manufacturing an semiconductor device, comprising:
creating a semiconductor substrate; and
forming an indium doped dielectric layer over the semiconductor substrate.

10. The method as recited in claim 9 wherein forming an indium doped dielectric layer includes forming an indium doped interlevel dielectric layer.

11. The method as recited in claim 9 wherein forming an indium doped dielectric layer includes forming an indium doped silicon dioxide layer.

12. The method as recited in claim 9 wherein forming an indium doped dielectric layer includes forming an indium doped dielectric layer to a thickness ranging from about 400 nm to about 1200 nm.

13. The method as recited in claim 9 wherein forming an indium doped dielectric layer includes forming an indium doped dielectric layer having an indium concentration ranging from about 1 mole weight percent to about 15 mole weight percent.

14. The method as recited in claim 13 further including forming an active region over the semiconductor substrate, and wherein forming an indium doped dielectric layer includes forming an indium doped dielectric layer over the active region.

15. The method as recited in claim 14 wherein forming an indium doped dielectric layer includes forming an indium doped dielectric layer using a manufacturing process selected from the group consisting of a physical vapor deposition process or a chemical vapor deposition process.

16. The method as recited in claim 9 wherein forming an indium doped dielectric layer includes forming an indium doped dielectric layer using a physical vapor deposition process employing a target that comprises silicon dioxide and indium.

17. The method as recited in claim 9 wherein forming an indium doped dielectric layer includes forming an indium doped dielectric layer using a pressure ranging from about 4 mTorr to about 8 mTorr, using a radio frequency (RF) power ranging from about 50 watts to about 550 watts and using a gas flow rate ranging from about 10 ccm to about 35 ccm.

18. An integrated device, comprising:
a first semiconductor device, including;
a semiconductor substrate; and
an indium doped dielectric layer located over the semiconductor substrate; and
a second semiconductor device located adjacent the first semiconductor device and over the semiconductor substrate.

19. The integrated device as recited in claim 18, wherein the first or second semiconductor device is a microelectronic device selected from the group consisting of:
a complementary metal oxide semiconductor (CMOS) device;
a bipolar device; and
a bipolar complementary metal oxide semiconductor (BiCMOS) device.

20. The integrated device as recited in claim 18, wherein the first or second semiconductor device is an optoelectronic device selected from the group consisting of:
a modulator;
a laser; and
a photodetector.
